(19) United States
(12) Patent Application Publication
(10) Pub. No.: US 2026/0089885 A1
(43) Pub. Date: Mar. 26, 2026

(54) SYSTEM AND METHOD FOR MONITORING LIQUID COOLANT IN AN INFORMATION HANDLING SYSTEM

(71) Applicant: DELL PRODUCTS L.P., Round Rock, TX (US)

(72) Inventors: Michael Stumpf, Cedar Park, TX (US); Sandor Farkas, Round Rock, TX (US)

(21) Appl. No.: 18/891,225

(22) Filed: Sep. 20, 2024

(51) Int. Cl. H05K 7/20; G06F 1/20

(52) U.S. Cl. CPC H05K 7/20281; G06F 1/203; G06F 1/206; H05K 7/20254; H05K 7/20272; G06F 2200/201

(57) ABSTRACT

A system includes a cooling distribution unit and an information handling system. The information handling system includes a cooling plate in fluid communication with the cooling distribution unit. The cooling distribution unit selectively circulates liquid coolant through the cooling plate. The information handling system further includes a leak sensor to detect the presence of liquid coolant leaks and a processor to communicate with the leak sensor and the cooling distribution unit. The process monitors the information handling system for leak detection via the leak sensor and diverts fluid flow from the cooling distribution unit away from the cooling plate when a leak is detected.

### FIELD OF THE DISCLOSURE

The present disclosure generally relates to information handling systems, and more particularly relates to monitoring liquid coolant in an information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A system is disclosed and includes a cooling distribution unit and an information handling system. The information handling system includes a cooling plate in fluid communication with the cooling distribution unit. The cooling distribution unit selectively circulates liquid coolant through the cooling plate. The information handling system further includes a leak sensor to detect the presence of liquid coolant leaks and a processor to communicate with the leak sensor and the cooling distribution unit. The process may monitor the information handling system for leak detection via the leak sensor and divert fluid flow from the cooling distribution unit away from the cooling plate when a leak is detected.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of computing system according to an embodiment of the present disclosure;

FIG. 2 is a block diagram of computing system according to another embodiment of the present disclosure;

FIG. 3 is a flow diagram of a method for monitoring liquid coolant in an information handling system according to an embodiment of the present disclosure; and

FIG. 4 is a diagram of a fluid ejector pump according to an embodiment of the present disclosure;

FIG. 5 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

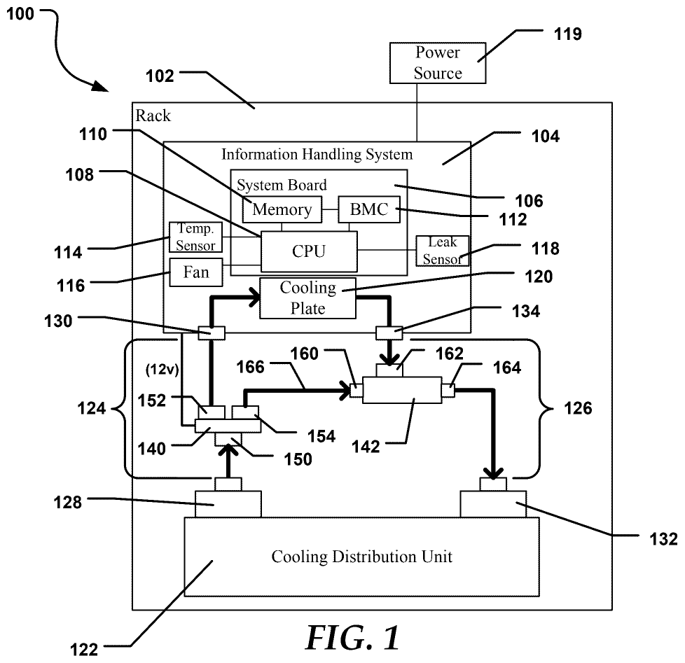

FIG. 1 illustrates a system 100 that may include a rack 102, or cabinet, in which an information handling system 104 is installed, or otherwise disposed. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As shown, the information handling system 104 may include a system board 106, or motherboard, on which a central processing unit (CPU) 108 is installed, or otherwise disposed. The information handling system 104 may also include a memory 110 coupled to the CPU 108. Moreover, a baseboard management controller 112 may be disposed on the system board 106 and may be coupled to the CPU 108 and the memory 110. Other components necessary to the operation of the information handling system 104, and well known in the art, may be disposed on the system board 106. The information handling system 104 may also include a temperature sensor 114, a fan 116 adjacent the CPU 108, and a leak sensor 118. For example, the leak sensor 118 may be an optical light sensor. Additionally, the information handling system 104 may be coupled to a power source 119. The power source 119 may be an alternating current (AC) power source, a direct current (DC) power source, or a combination thereof. The power source 119 may provide power to all of the components described herein that required power to operate.

FIG. 1 further shows a cooling plate 120 adjacent the system board 106. Specifically, the cooling plate 120 is adjacent the CPU 108 which may generate and emit a substantial amount of heat during operation of the information handling system 102. A cooling distribution unit 122 may be connected to the cooling plate 120 via a coolant supply line 124 and a coolant return line 126. Specifically, the coolant supply line 124 is connected between an outlet manifold 128, or cold manifold, of the cooling distribution unit 122 and an inlet 130 of the information handling system 104. Further, the coolant return line 126 is connected between an inlet manifold 132, or hot manifold, of the cooling distribution unit 122 and an outlet 134 of the information handling system 104.

As illustrated, a valve 140 may be disposed along the supply line 124 and a pump 142 may be disposed along the return line 126. Accordingly, the valve 140 is in fluid communication with the supply line 124 and the pump 142 is in fluid communication with the return line 126. The valve 140 may include a supply inlet 150, a supply outlet 152, and a bypass outlet 154. The pump 142 may include a bypass inlet 160, a return inlet 162, and a return outlet 164. Further, a bypass line 166 may be connected between the bypass outlet 154 of the valve 140 and the bypass inlet 160 of the pump. In a particular embodiment, the valve 140 may be a 12 volt (v) solenoid valve that is powered by the information handling system 104. Further, the valve 140 remains in a bypass configuration when powered off. In other words, when the valve 140 is powered off, flow to the supply line 124 is blocked and flow to the bypass line 166 is permitted. When the valve 140 is powered on, the valve 140 may be moved to a supply configuration and flow may be permitted to the supply line 124. In the supply configuration, flow to the bypass line 166 is blocked.

It is to be understood that the cooling distribution unit 122 is in fluid communication with the cooling plate 120 via the coolant supply line 124 and the coolant return line 126. During operation, the cooling distribution unit 122 may circulate coolant to the cooling plate 120 via the coolant supply line 124 and the coolant return line 126 in order to lower the temperature of the cooling plate 120 and therefore, transfer heat generated by the CPU 108 away from the CPU 108, and the system board 106, in order to lower the operating temperature of the CPU 108, the system board 106, and the other components disposed on the system board 106. In the event a leak is detected in the information handling system 104, e.g., by the leak sensor 118, the valve 140 may be de-energized, i.e., powered off, to move the valve 140 from a supply configuration, in which liquid coolant flows through the supply outlet 152 and through the cooling plate 120, to a bypass configuration, in which liquid coolant is diverted through the bypass outlet 154 to the bypass line 166 and directly to the pump 142. In the bypass configuration, the cooling plate 120 is bypassed such that fluid flow is prevented to the cooling plate 120 and further leaking is prevented, or substantially minimized, to prevent damage to the information handling system 104 and the components therein.

Note that, in the presence of a coolant liquid leak, a typical information handling system may, upon detection of the leak, power down the information handling system to reduce the chance for the leaked coolant liquid to cause damage to the information handling system through shorting of the circuits of the information handling system. In this regard, as noted above, the valve 140 defaults to the bypass configuration, and the coolant liquid is drawn from the cooling plate 120 passively through the action of pump 142, as described further below.

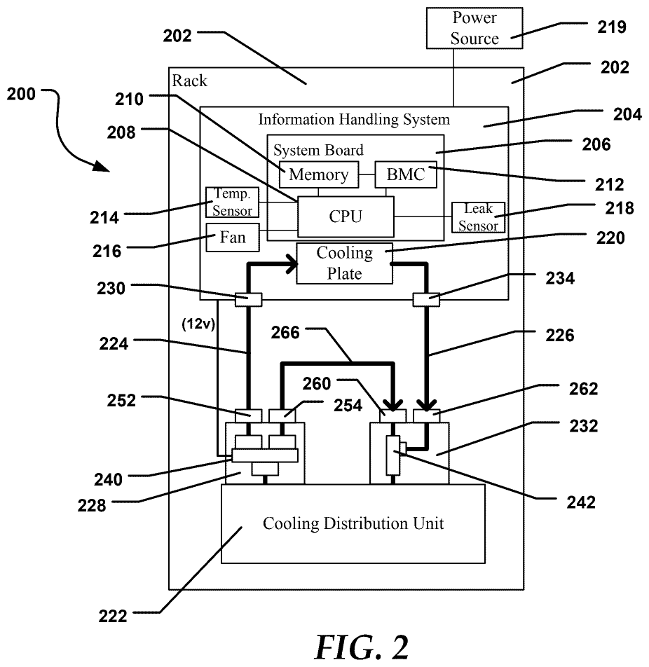

Referring to FIG. 2 another embodiment of a system 200 is illustrated and may include a rack 202, or cabinet, in which an information handling system 204 is installed, or otherwise disposed. The information handling system 204 may include a system board 206, or motherboard, on which a central processing unit (CPU) 208 is installed, or otherwise disposed. The information handling system 204 may also include a memory 210 coupled to the CPU 208. Moreover, a baseboard management controller 212 may be disposed on the system board 206 and may be coupled to the CPU 208 and the memory 210. Other components necessary to the operation of the information handling system 204, and well known in the art, may be disposed on the system board 206. The information handling system 204 may also include a temperature sensor 214, a fan 216 adjacent the CPU 208, and a leak sensor 218. For example, the leak sensor 218 may be an optical light sensor. Additionally, the information handling system 204 may be coupled to a power source 219. The power source 219 may be an alternating current (AC) power source, a direct current (DC) power source, or a combination thereof. The power source 219 may provide power to all of the components described herein that required power to operate.

FIG. 2 further shows a cooling plate 220 adjacent the system board 206. Specifically, the cooling plate 220 is adjacent the CPU 208 which may generate and emit a substantial amount of heat during operation of the information handling system 202. A cooling distribution unit 222 may be connected to the cooling plate 220 via a coolant supply line 224 and a coolant return line 226. Specifically, the coolant supply line 224 is connected between an outlet 228, or cold manifold, of the cooling distribution unit 222 and an inlet 230 of the information handling system 204. Further, the coolant return line 226 is connected between an inlet 232, or hot manifold, of the cooling distribution unit 222 and an outlet 234 of the information handling system 204.

As illustrated, a valve 240 may be disposed within the outlet manifold 228 of the cooling distribution unit 222 and a pump 242 may be disposed within the inlet manifold 232 of the cooling distribution unit 222. The outlet manifold 228 may include a supply outlet 252 and a bypass outlet 254. The inlet manifold 232 may include a bypass inlet 260 and a return inlet 262. Moreover, a bypass line 266 may be connected between the bypass outlet 254 of the outlet manifold 228 and the bypass inlet 260 of the of the inlet manifold 232. In a particular embodiment, the valve 240 may be a 12 volt (v) solenoid valve that is powered by the information handling system 204. Further, the valve 240 remains in a bypass position when powered off. In other words, when the valve 240 is powered off, flow to the supply line 224 is blocked and flow to the bypass line 266 is permitted. When the valve 240 is powered on, flow may be permitted to the supply line 224 and flow to the bypass line 266 is blocked. It is to be understood that the valve 240 is in fluid communication with the supply line 224 and the pump 242 is in fluid communication with the return line 226.

It is to be understood that the cooling distribution unit 222 is in fluid communication with the cooling plate 220 via the coolant supply line 224 and the coolant return line 226. During operation, the cooling distribution unit 222 may circulate coolant to the cooling plate 220 via the coolant supply line 224 and the coolant return line 226 in order to lower the temperature of the cooling plate 220 and therefore, transfer heat generated by the CPU 208 away from the CPU 208, and the system board 206, in order to lower the operating temperature of the CPU 208, the system board 206, and the other components disposed on the system board 206. In the event a leak is detected in the information handling system 204, e.g., by the leak sensor 218, the valve 240 may be de-energized, i.e., powered off, to move the valve 240 from a supply configuration, in which liquid coolant flows through the supply outlet 252 and through the cooling plate 220, to a bypass configuration, in which liquid coolant is diverted through the bypass outlet 254 to the bypass line 266 and directly to the pump 242. In the bypass configuration, the cooling plate 220 is bypassed such that fluid flow is prevented to the cooling plate 220 and further leaking is prevented, or substantially minimized, to prevent damage to the information handling system 204 and the components therein.

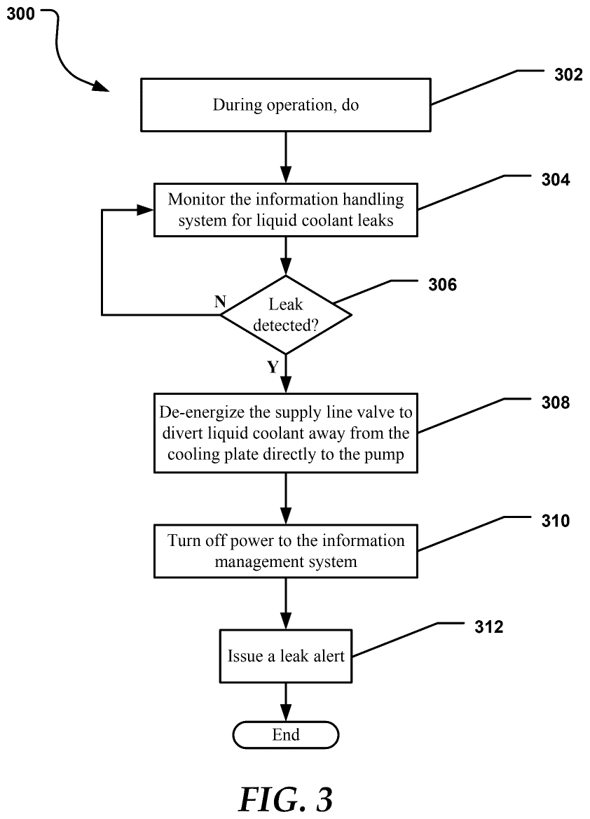

FIG. 3 is a flow diagram of a method 300 for monitoring liquid coolant in an information handling system, e.g., information handling system 104 or information handling system 204, according to at least one embodiment of the present disclosure, starting at block 302. It will be readily appreciated that not every method step set forth in this flow diagram is always necessary, and that certain steps of the methods may be combined, performed simultaneously, in a different order, or perhaps omitted, without varying from the scope of the disclosure. The method steps depicted in FIG. 3 may be executed, or employed in whole, or in part, by the baseboard management controller 112, 212, the CPU 108, 208 of the information handling system 104, 204 a combination thereof, or any other type of controller, device, module, processor, or any combination thereof, operable to employ, or otherwise execute, all, or portions of, the method 300 of FIG. 3.

Beginning at block 302, the method 300 may include entering a do loop in which during operation, the following steps are performed. At block 304, the method 300 may include monitoring the information handling system 104, 204 for liquid coolant leaks. At decision step 306, the method 300 determines whether a leak is detected. If not, the method 300 returns to block 304 and continues as described herein. On the other hand, at decision step 306, if a leak is detected, the method 300 may proceed to block 308 and may include de-energizing, or powering off, the supply line valve 140, 240 to move the valve 140, 240 from a supply configuration to a bypass configuration to divert liquid coolant away from the cooling plate 120, 220 and directly to the pump 142, 242. As such, liquid coolant is prevented from flowing through the cooling plate 120, 220 and allowed to flow through the bypass line 166, 266 to the pump 142, 242. Then, at block 310, the method 300 may include turning off power to the information management system 104, 204. At block 312, the method 300 may include issuing an alert, e.g., a leak alert. Thereafter, the method 300 may end.

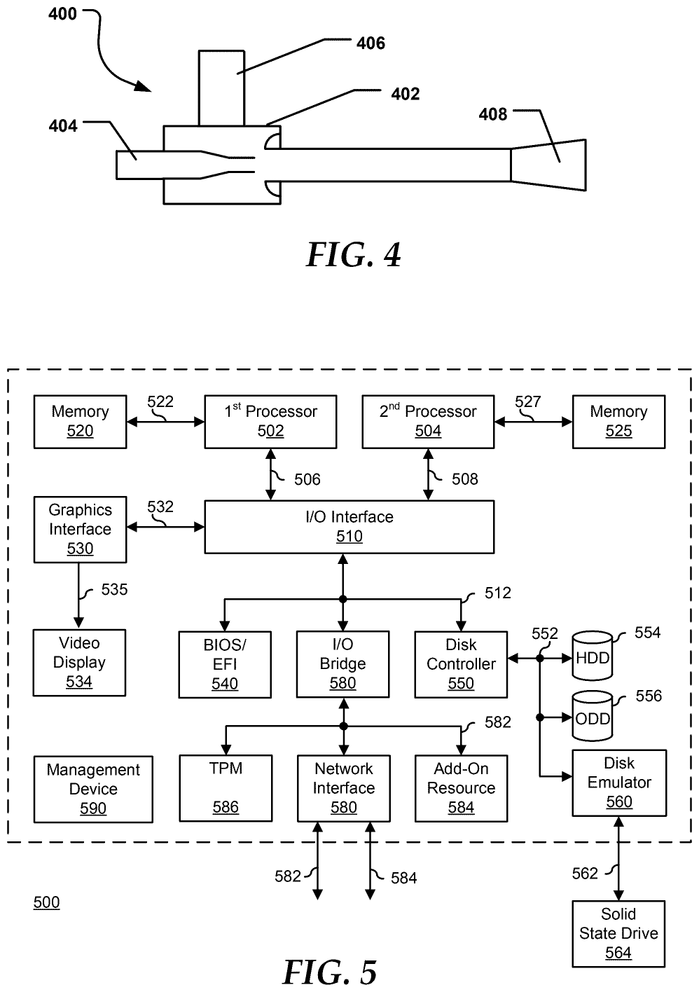

Referring briefly to FIG. 4, a fluid ejector pump 400 is illustrated. It is to be understood the fluid ejector pump 400 may be used in lieu of the pump 142 in FIG. 1 or the pump 242 in FIG. 2. As shown, the pump 400 includes a pump housing 402 having a first inlet 404 and a second inlet 406. Moreover, the pump 400 has an outlet 408. It is to be understood that the fluid ejector pump 400 may utilize the pressure energy of a high-pressure liquid stream (i.e., the flow from first inlet 404 to outlet 408) to provide a negative pressure to draw fluid from second inlet 406 to outlet 408.

FIG. 5 shows a generalized embodiment of an information handling system 500 according to an embodiment of the present disclosure. Information handling system 500 may be substantially similar to the information handling system 104 of FIG. 1 or the information handling system 204 of FIG. 2. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below and operates to perform one or more of the methods described herein. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 564, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 564, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532 and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 5394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512 or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500.

Management device 590 can operate off of a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A system comprising:
a cooling distribution unit;
an information handling system, comprising:
a cooling plate in fluid communication with the cooling distribution unit, wherein the cooling distribution unit selectively circulates liquid coolant through the cooling plate;
a leak sensor to detect the presence of liquid coolant leaks; and
a processor to communicate with the leak sensor and the cooling distribution unit, the processor to:
monitor the information handling system for leak detection via the leak sensor; and
divert fluid flow from the cooling distribution unit away from the cooling plate when a leak is detected.

2. The system of claim 1, wherein the processor further to:
de-energize the information handling system when the leaked is detected.

3. The system of claim 2, wherein the processor further to:
issue a leak alert.

4. The system of claim 1, further comprising:
a supply line connected between the cooling distribution unit and the cooling plate;
a return line connected between the cooling distribution unit and the cooling plate; and
a valve disposed along the supply line, the valve including a supply configuration, in which liquid coolant flows to the cooling plate, and a bypass configuration in which liquid coolant is prevented from flowing to the cooling plate.

5. The system of claim 4, further comprising:
a pump disposed along the return line; and
a bypass line connected between the valve and the pump, wherein in the bypass configuration liquid coolant flows between the valve and the pump.

6. The system of claim 5, wherein the processor further to:
selectively move the valve from the supply configuration to the bypass configuration when a leak is detected by the leak sensor.

7. The system of claim 1, wherein the cooling distribution unit further comprises:
an outlet manifold;
a supply line coupled between the outlet manifold and the cooling plate;
an inlet manifold;
a return line coupled between the cooling plate and the inlet manifold; and
a bypass line coupled between the outlet manifold and the inlet manifold.

8. The system of claim 1, wherein the cooling distribution unit further comprises:
a valve disposed within the outlet manifold, the valve including a supply configuration, in which liquid coolant flows to the cooling plate, and a bypass configuration in which liquid coolant is prevented from flowing to the cooling plate.

9. The system of claim 8, wherein the cooling distribution unit further comprises:
a pump disposed within the inlet manifold, wherein in the bypass configuration liquid coolant flows between the valve and the pump.

10. The system of claim 9, wherein the processor further to:
selectively move the valve from the supply configuration to the bypass configuration when a leak is detected by the leak sensor.

11. A method comprising:
monitoring an information handling system for liquid coolant leaks via a leak sensor; and
preventing fluid flow to a cooling plate within the information handling system when a leak is detected.

12. The method of claim 11, further comprising:
powering off the information handling system when a leak is detected.

13. The method of claim 12, further comprising:
issuing a leak alert when a leak is detected.

14. The method of claim 11, further comprising:
selectively moving a valve disposed along a supply line to the cooling plate, from a supply configuration, in which liquid coolant flows to the cooling plate, and a bypass configuration in which liquid coolant is prevented from flowing to the cooling plate, when a leak is detected.

15. A system comprising:
a cooling distribution unit, comprising:
a supply line;
a return line; and
an information handling system, comprising:
a cooling plate in fluid communication with the supply line and the return line;
a leak sensor to detect the presence of liquid coolant leaks within the information handling system; and
a processor to communicate with the leak sensor and the cooling distribution unit, to processor to:
monitor the information handling system for leak detection via the leak sensor; and
divert fluid flow from the supply line directly to the return line and away from the cooling plate when a leak is detected.

16. The system of claim 15, wherein the processor further to:
de-energize the information handling system when the leaked is detected; and. issue a leak alert.

17. The system of claim 16, further comprising:
a valve in fluid communication with the supply line, the valve including a supply configuration, in which liquid coolant flows to the cooling plate, and a bypass configuration in which liquid coolant is prevented from flowing to the cooling plate

18. The system of claim 17, further comprising:
a pump in fluid communication with the return line; and
a bypass line connected between the valve and the pump, wherein in the bypass configuration liquid coolant flows between the valve and the pump.

19. The system of claim 18, wherein the cooling distribution unit further comprises:
an outlet manifold and the valve is disposed within the outlet manifold.

20. The system of claim 18, wherein the cooling distribution unit further comprises:
an inlet manifold and the pump is disposed within the inlet manifold.
